(19) United States
(12) Patent Application Publication
(10) Pub. No.: US 2005/0098337 A1
(43) Pub. Date: May 12, 2005

(54) Common grounding strap

(76) Inventors: James V. Brock, Crothersville, IN (US); David N. Gater, Scottsburg, IN (US)

Correspondence Address: Clifford W. Browning, Suite 3700, 111 Monument Circle, Indianapolis, IN, 46204-5137, US

(21) Appl. No.: 10/983,352

(22) Filed: Nov. 8, 2004

Related U.S. Application Data
(60) Provisional application No. 60/518,774, filed on Nov. 10, 2003.

(51) Int. Cl. H05K 5/02

(52) U.S. Cl. 174/51

(57) ABSTRACT

A common grounding strap, comprising a strip of conductive material sized to span multiple electrical devices within a non-conductive or conductive multi-gang box, each electrical device having a conductive fastener to fasten the electrical device to the multi-gang box, and apparatus for simultaneously mounting the strip of conductive material to each electrical device to provide an integrated ground connection between the multiple electrical devices.

This application claims the benefit of pending U.S. Provisional Patent Application Ser. No. 60/518,774, filed Nov. 10, 2003.

This application relates generally to devices and methods for earth grounding electrical switches and receptacles, and more specifically to a device and method for grounding switches and receptacles in non-conductive and conductive multi-gang boxes.

### BACKGROUND OF THE INVENTION

Some new homes have many switches and receptacles that are mounted in non-conductive or conductive multi-gang boxes and that have been left ungrounded because some electricians do not want to take the extra 15 or 20 minutes it would have taken in the typical three- or four-gang box to jumper earth grounds to all of the individual switches or receptacles mounted within the box. It is so time consuming that all of the switches or receptacles in a multi-gang box often do not get grounded. Individual ground jumpers in multi-gang boxes also take up lots of room and make the individual switches and receptacles harder to install in the multi-gang boxes. Existing ground jumpers can also be unsafe because in the process of pushing multiple switches or receptacles with ground jumpers attached into a multi-gang box, the ground jumpers can be loosened, and when loosened, they can get into the “hot” terminals of the switches or receptacles, causing dangerous shorts that could result in a fire.

### SUMMARY OF THE INVENTION

The common grounding strap of the present invention provides a fast and simple way of earth grounding all of the multiple switches or receptacles in a nonconductive and conductive multi-gang. With the common grounding strap of the present invention, the task of grounding all of the switches or receptacles in multi-gang boxes not only becomes very simple, but the need to install and deal with ground jumpers wired between the individual switches or receptacles is eliminated. When the common grounding strap of the present invention is in use, all the switches or receptacles in the multi-gang box are electrically connected together to form an integrated earth ground across all the individual switchgear receptacles. The common grounding strap eliminates all jumpers inside the multi-gang box except for one. There needs to be one jumper attached to one of the switches or receptacles that goes to an earth ground, but that one jumper is all that needs to be installed and shoved to the back of multi-gang box safely away from “hot” terminals of all the switches or receptacles mounted therein.

### BRIEF DESCRIPTION OF THE DRAWING FIGURES

FIG. 1 is a perspective view of a preferred common grounding strap of the present invention.

FIG. 2 is a perspective view of an exemplary three-switch non-conductive multi-gang switch box, with the common grounding strap of the present invention in use to form an integrated earth ground for the three switches illustrated.

### DETAILED DESCRIPTION OF THE PREFERRED EMBODIMENT

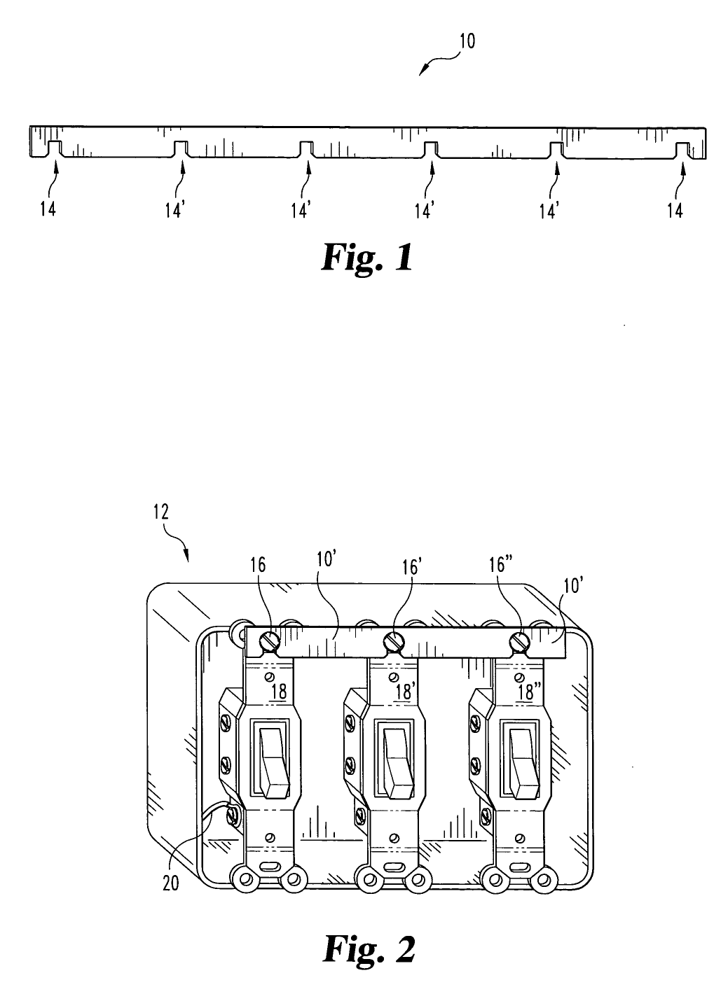

Referring now to FIGS. 1 and 2, the following description discloses how to construct a 10-inch common grounding strap of the present invention 10 (FIG. 1) that will fit a standard non-conductive or conductive six-gang switch or receptacle box, but the common grounding strap 10 could be cut down or cut larger initially to fit any size multi-gang switch or receptacle box. For example, to fashion a common grounding strap 10′ to fit a standard three-gang box 12 illustrated in FIG. 2, an electrician can simply shear the common ground strap 10 to the length needed. The remaining portion of common ground strap 10 can be saved and used in any other multi-gang switch or receptacle boxes.

Referring to FIG. 1, the preferred embodiment of the common ground strap 10 of the present invention is formed from copper sheets of approximately 24 gauge thickness that is sheared into ½ inch by 10-inch strips. The material of choice is copper, which is an excellent conductor of electricity. Starting ½ of an inch from the end of each copper strip a notch 14 is cut ¼ of an inch deep and 3/16 of an inch wide. An identical notch 14′ is cut every 1.8 inches thereafter. The length of the common grounding strap 10 of the present invention can vary on demand, and could be carried in continuous rolls or standard length strip form.

When finished with this simple construction process, the notches 14, 14′ of common grounding strap 10 of the present invention will fit over the adjoining top mounting screws of the switches or receptacles that mount the switches or receptacles in the multi-gang box. Referring now to FIG. 2, and the three-gang switch box illustrated without all customary wires for ease of understanding, before the top mounting screws 16, 16′ 16″ of the illustrated switches 18, 18′, 18″ are tightened to the switch box 12, the common grounding strip 10′ is slid behind the head of the screws 16, 16′, 16″ and in front of the switches 18, 18′, 18.″ When the top switch mounting screws 16, 16′, 16″ are then tightened, all the switches 18, 18′, 18″ are connected together with a common grounding strap 10′. FIG. 2 illustrates the exemplary application of common grounding strip 10 (FIG. 1) to a three-gang switch box by cutting common ground strip 10 down to a size 10′ that will fit a three-gang switch box 12. Earth ground jumper 20 attached to switch 18 then electrically connects the metallic body of switch 18 to common ground strap 10′, which in turn now electrically connects the earth ground jumper 20 to the metallic bodies of switches 18′, 18″, providing an earth ground connection for switches 18′, 18″ to switch 18 that is the equivalent of the earth ground jumper 20 attached to switch 18.

In the same manner, the common grounding strap 10 of the present invention can be used to provide a common earth ground for multi-gang receptacle boxes.

The principal uses of the common grounding strap 10 of the present invention will be in the electrical field, where it will be installed in multi-gang snap switchboxes or multi-gang receptacle boxes of non-conductive material to serve as an earth ground conducting strap across all the switches or receptacles to make installation of switches or receptacles in multi-gang boxes easier and quicker. When it is placed between the head of the screw that holds each switch or receptacle to a non-conductive box and the metal body of the switch or receptacle, only one switch or receptacle is required to have a direct earth ground jumper. The common ground strap 10 of the present invention provides an earth ground connection to the one earth ground jumper for the remaining switches or receptacles in the box, and most importantly, the common grounding strap is installed after the switches or receptacles have been “hot” wired and mounted within the multi-gang boxes. Tightening the screws 16, 16′, 16″ for example, then completes installation of the common ground strap 10. The common ground strap 10 even works when the switches or receptacles are left loose in the multi-gang boxes by the pressure standard multi-gang box cover plates apply to the switches or receptacles when the cover plates are tightened with a mounting screw.

This method and product will make the job of wiring switch and receptacle multi-gang boxes much faster and safer than ever known or done in the past. This will also make the jobs of code inspectors much easier, because they will no longer have to search inside the multi-gang boxes to make sure that all devices therein have been properly grounded. Inspectors will simply look to see if one is grounded to earth by a jumper and then look for the prominent common ground strap 10 of the present invention. The common ground strap 10 of the present invention could also be useful in old house switch and receptacle multi-gang boxes as many old switches and receptacles were also not earth grounded. This common ground strap 10 could be installed to ground all, if one earth ground wire is present in the multi-gang box.

1. A common grounding strap, comprising:
a strip of conductive material sized to span multiple electrical devices within a non-conductive or conductive multi-gang box, each electrical device having a conductive fastener to fasten the electrical device to the multi-gang box, and
means for simultaneously mounting the strip of conductive material to each electrical device to provide an integrated ground connection between the multiple electrical devices.

2. The common grounding strap of claim 1 wherein the strip of conductive material is a strip of copper.

3. The common grounding strap of claim 2 wherein the means for mounting the strip of copper includes notches cut out of the strip of copper to receive therein the conductive fasteners of each electrical device.

4. The common grounding strap of claim 3 wherein the electrical devices are electrical switches.

5. The common grounding strap of claim 3 wherein the electrical devices are electrical receptacles.

6. A method of providing an integrated ground for multiple electrical devices within a non-conductive or conductive multi-gang box, comprising the steps of:
providing a strip of conductive material sized to span multiple electrical devices within a non-conductive or conductive multi-gang box, each electrical device having a conductive fastener to fasten the electrical device to the multi-gang box
mounting the strip of conductive material to each electrical device to provide an integrated ground connection between the multiple electrical devices.

7. The method of claim 6 wherein the strip of conductive material is a strip of copper.

8. The method of claim 7 wherein the means for mounting the strip of copper includes notches cut out of the strip of copper to receive therein the conductive fasteners of each electrical device.

9. The method of claim 8 wherein the electrical devices are electrical switches.

10. The method of claim 8 wherein the electrical devices are electrical receptacles.
